(19) United States
(12) Patent Application Publication
(10) Pub. No.: US 2020/0357772 A1
(43) Pub. Date: Nov. 12, 2020

(54) METHOD AND APPARATUS FOR STACKING WARPED CHIPS TO ASSEMBLE THREE-DIMENSIONAL INTEGRATED CIRCUITS

(71) Applicant: Oracle International Corporation, Redwood Shores, CA (US)

(72) Inventors: Yue Zhang, San Mateo, CA (US); Michael H. S. Dayringer, Union City, CA (US); Nyles Nettleton, Cupertino, CA (US)

(73) Assignee: Oracle International Corporation, Redwood Shores, CA (US)

(21) Appl. No.: 16/937,567

(22) Filed: Jul. 23, 2020

Related U.S. Application Data
(62) Division of application No. 15/917,195, filed on Mar. 9, 2018.

(51) Int. Cl. H01L 25/065; H01L 23/00; H01L 27/06

(52) U.S. Cl. CPC H01L 25/0657; H01L 24/26; H01L 2225/06568; H01L 2224/16145; H01L 27/0688

(57) ABSTRACT

A method for constructing a ramp-stacked chip assembly starts by obtaining a set of semiconductor chips, including a first chip and a set of additional chips. Next, the method stacks the set of additional chips one at a time over the first chip, wherein each additional chip is horizontally offset from a preceding additional chip to form a ramp-stack. While stacking each additional chip, the method: applies an adhesive layer to a surface of a preceding chip in the ramp-stack; and uses a vacuum tool to pick up the additional chip and place the additional chip on the adhesive layer of the preceding chip. During this pick-and-place process, the vacuum tool spans most of a surface of the additional chip and also provides planar support for the additional chip, which causes a holding force of the vacuum tool to flatten the additional chip prior to placement on the preceding chip.

### CROSS-REFERENCE TO RELATED APPLICATION

This application is a divisional application of, and hereby claims priority under 35 U.S.C. § 120 to, pending U.S. patent application Ser. No. 15/917,195, entitled “Method and Apparatus for Stacking Warped Chips to Assemble Three-Dimensional Integrated Circuits,” by inventors Yue Zhang, et al., filed on 9 Mar. 2018.

### BACKGROUND

### Field

The disclosed embodiments generally relate to techniques for manufacturing three-dimensional (3D) integrated circuits. More specifically, the disclosed embodiments relate to a method and an apparatus for stacking warped chips while assembling a 3D integrated circuit.

### Related Art

Semiconductor density scaling has provided significant benefits for those seeking to improve the quality of future computing systems. Historically, designers have been able to rely on continually shrinking feature sizes and associated reductions in transistor cost to drive performance improvements. However, as the rate of this density scaling slows, we are left looking for new methods to provide the cost and performance improvements the industry has come to rely on. Recently developed 3D packaging techniques provide a way to integrate multiple semiconductor dice in close proximity to each other, but only if we can solve the mechanical, electrical, and thermal problems inherent in dealing with multiple dice.

Ramp-stacked chip packaging is one such promising technique for tightly integrating multiple dice to realize benefits from shorter wires, lower parasitics, and higher transistor counts. Other techniques for assembling 3D integrated circuits (ICs), such as through-silicon via (TSV)-based stacking and wirebond stacking, have also been investigated. At the core of all of these techniques is the idea of thinning chips and stacking them on top of each other to get physical proximity to be as tight as possible. The advantages of such techniques arise from the chips being planar devices. Hence, providing additional chip thickness beyond a few tens of microns mostly serves to improve mechanical stiffness, while providing no benefit for electrical properties.

As noted, thinned chips are at the core of modern 3D packaging techniques. However, they are costly to produce and handle due to their reduced mechanical reliability. The chip-fabrication process involves embedding many different materials together at different temperatures, leading to internal stresses in the chips that can cause warpage. Cracking and chipping of thinned dice during handling and preparation are also serious issues that increase the cost of 3D IC packaging. Die warpage is especially problematic because it can be hard to detect with visual inspection, and can lead to low yields during chip bonding operations, which usually require two co-planar surfaces to be joined over a large area.

Hence, what is needed is a technique for manufacturing 3D ICs without the above-described drawbacks related to die warpage and chip bonding.

### SUMMARY

The disclosed embodiments relate to a method for constructing a ramp-stacked chip assembly. The method starts by obtaining a set of semiconductor chips, including a first chip and a set of additional chips. Next, the method stacks the set of additional chips one at a time over the first chip, wherein each additional chip is horizontally offset from a preceding additional chip to form a ramp-stack. While stacking each additional chip, the method: applies an adhesive layer to a surface of a preceding chip in the ramp-stack; and uses a vacuum tool to pick up the additional chip and place the additional chip on the adhesive layer of the preceding chip. During this pick-and-place process, the vacuum tool spans most of a surface of the additional chip and also provides planar support for the additional chip, which causes a holding force of the vacuum tool to flatten the additional chip prior to placement on the preceding chip.

In some embodiments, the first chip is thicker than the additional chips to provide additional stiffness and reduce warpage.

In some embodiments, the first chip is a dummy chip that contains no active circuitry.

In some embodiments, the first chip is a functioning chip that includes active circuitry.

In some embodiments, the planar support is provided by a perimeter of a vacuum cavity in the vacuum tool, and also support pillars within the vacuum cavity.

In some embodiments, after each additional chip is placed on the adhesive layer of a preceding chip, the method further comprises snap-curing the adhesive layer using ultra-violet light (UV).

In some embodiments, after all of the additional chips are placed and snap-cured, the method further comprises performing a heat-based batch-curing operation on the entire ramp-stack to complete a permanent bonding process for the adhesive layers.

In some embodiments, the method further comprises: attaching solder balls to bond pads located on edges of chips in the ramp-stack; and affixing a ramp-component chip to the ramp-stack so that corresponding bond pads on the ramp-component chip are attached to the solder balls.

In some embodiments, the first chip and the additional chips were previously thinned through a chemical-mechanical polishing (CMP) operation prior to stacking.

### BRIEF DESCRIPTION OF THE FIGURES

FIG. 1A illustrates a ramp-stacked chip assembly with a dummy first chip in accordance with the disclosed embodiments.

FIG. 1B illustrates a ramp-stacked chip assembly with a functioning first chip in accordance with the disclosed embodiments.

FIG. 2A illustrates a tool that provides a vacuum to flatten a semiconductor die in accordance with the disclosed embodiments.

FIG. 2B illustrates the tool being used to pick up a semiconductor die in accordance with the disclosed embodiments.

FIG. 3A presents a flow chart of a process for constructing a ramp-stacked chip assembly in accordance with the disclosed embodiments.

FIG. 3B presents a flow chart illustrating in more detail the operations involved in performing step 304 in FIG. 3A in accordance with the disclosed embodiments.

FIG. 4 illustrates a computer system which includes a ramp-stacked chip assembly in accordance with the disclosed embodiments.

### DETAILED DESCRIPTION

The following description is presented to enable any person skilled in the art to make and use the present embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present embodiments. Thus, the present embodiments are not limited to the embodiments shown, but are to be accorded the widest scope consistent with the principles and features disclosed herein.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium. Furthermore, the methods and processes described below can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

### Details

The disclosed embodiments provide a process for constructing a ramp-stacked chip assembly. This process operates by temporarily holding a chip (also referred to as a “die”) flat during a chip-to-chip bonding step, while quickly bonding the chip by snap-curing an adhesive layer so that the chip remains flat after bonding. After all of the chips are bonded to form a ramp-stack, a heat-based batch-curing operation is performed on the entire ramp-stack to complete a permanent bonding process for the adhesive layers. The above-described process is fast, to keep the cost of such processing low, and can be implemented using only small changes to standard flip-chip bonding equipment.

The ramp-stack construction process involves three main operations. First, we prepare a flat surface to start building the stack. We can either use a blank thick silicon piece as the starting die or use a thick functioning chip. Second, a special vacuum tool is used to flatten a warped die and hold it flat during bonding. Third, a technique for quickly bonding the die to a flat surface is used so that the die stays flat.

### Preparing a Flat Surface as the Starting Point of the Stack

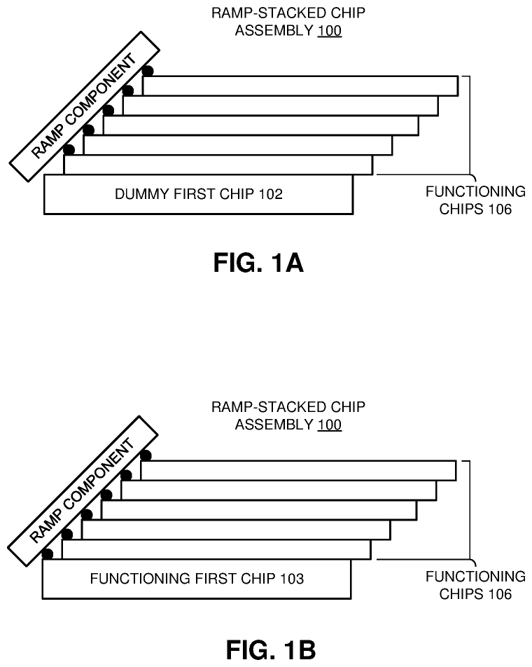

Typical thicknesses for thinned dice are below 100 μm, so thinned silicon dice are mechanically weak. To alleviate this problem, the first chip in the stack should ideally be thick and flat, so that it provides enough mechanical strength to hold the following dice flat. Note that there are at least two choices for the first chip. A blank silicon piece that is thick can serve as a dummy first chip 102 as is illustrated in FIG. 1A. Blank silicon is stress free and thus is flat. We can start putting adhesive on the blank silicon and then put down the first functioning chip. However, this blank silicon piece will be permanently embedded in the stack, which means a five-die stack will only have four functioning chips 106. Another option is to use a functioning first chip 103 that is thicker (e.g., 200-300 μm) as is illustrated in FIG. 1B. Even though the functioning chip has internal stress due to the active device and metal layers, its warpage is not going to be as significant when the die is thick. In this case, a five-die stack will have five functioning chips 106, wherein only the first chip is thicker.

### Vacuum Flattening a Chip

As mentioned earlier, most chips in the ramp-stack are thinned to below 100 μm. At these thicknesses, the silicon is more flexible and can be bent and warped by weak forces. Taking advantage of this flexibility, we propose to use air pressure against one surface of the chip to push, while providing a flat backing that is pushed against. The pressure differential is made by drawing a vacuum on one side of the chip. Air pressure from the other side pushes the chip against the special tool, flattening it and holding it against the tool for handling and manipulation.

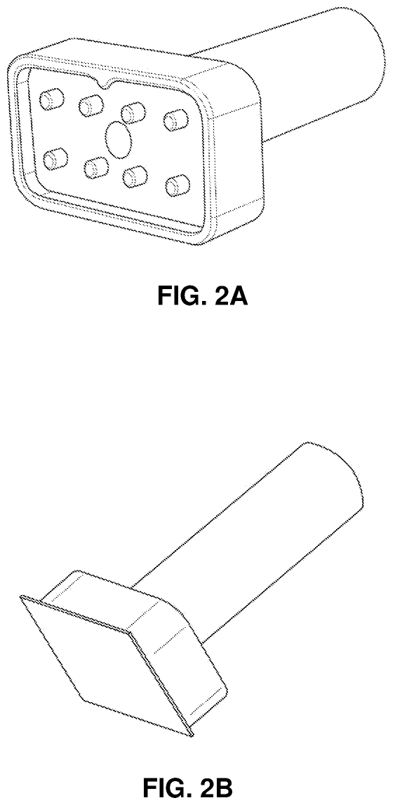

This technique requires a specially designed tool that not only provides a flat surface to push against, but also a good seal to the die for the vacuum, and good air flow in the associated vacuum chamber to ensure an even air pressure differential over the entire chip surface. In addition, the tool should ideally be designed to cover as much chip area as possible to ensure that the entire chip is flattened. One embodiment of such a tool is illustrated in FIG. 2A, while FIG. 2B illustrates a die being held flat by the tool's vacuum.

Note that the large vacuum cavity of this tool ensures even pressure over the die surface, while the support pillars provide a backstop to keep the die planar. Moreover, the perimeter of the tool seals to the die surface, ensuring that a good vacuum can be drawn quickly and without leaks.

### Fast Bonding to a Flat Surface

Though the special tool described above can temporarily hold a warped die flat, it is necessary that the die stays flat after bonding so that more chips can be added to the stack. Because stack building in this way is a serial process, the speed of the bonding step can be a major factor in the cost of this style of packaging. Therefore, we want to minimize the amount of time spent bonding each die.

We propose using a two-stage bonding process, where the first stage is a fast bond that holds the die flat temporarily, and the second stage is a bulk-curing process for the entire stack of dice in parallel. Such a two-stage process requires an adhesive that can be snap-cured, typically with a large input of energy to catalyze a chemical reaction in the adhesive. Because heat flow can be slow without physical contact and is more difficult to control, we propose using an adhesive that can be quickly cured with high-energy UV light. Note that a UV light can be turned on and off quickly, and preventing the UV light from affecting undesired areas only requires simple shielding. This adhesive, with proper formulation, can also contain the necessary compounds to allow for a slower and more-permanent heat-based curing operation later in the process. One such adhesive on the market today is EPO-TEK OG198-54 produced by Epoxy Technology, Inc., of Billerica, Mass.

### Process of Constructing a Ramp-Stacked Chip Assembly

In summary, the above-described process operates by picking up a warped die using the above-described vacuum tool and flattening it with air pressure. The flattened die is then placed against a prepared, flat surface which has a UV-compatible adhesive applied to it. Once the two dice are properly aligned, they are exposed to UV light to snap-cure the adhesive around the edges, which bonds the two dice and keeps them flat. Once the entire stack is complete, the adhesive can be fully heat-cured.

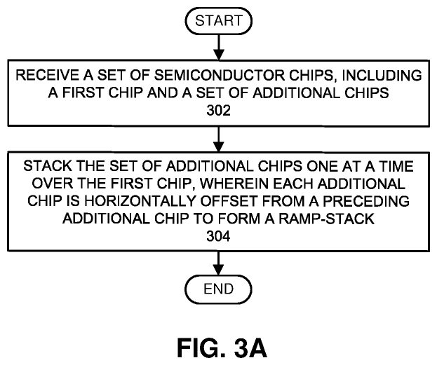

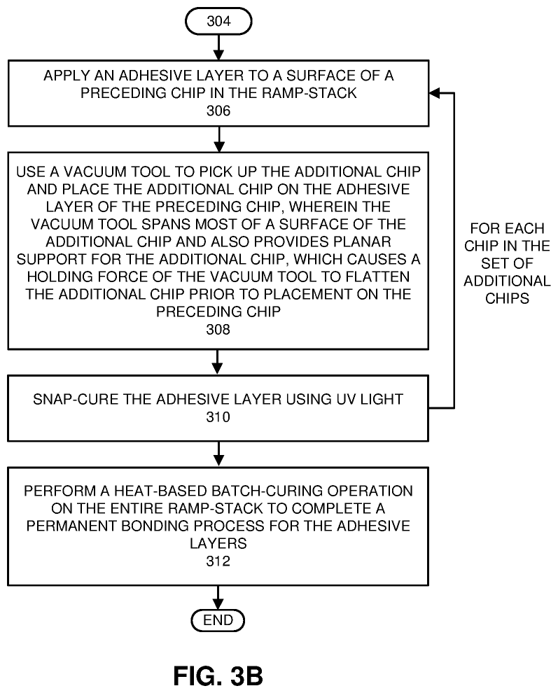

More specifically, FIG. 3A presents a flow chart of the process for constructing a ramp-stacked chip assembly in accordance with the disclosed embodiments. This process starts by receiving a set of semiconductor chips, including a first chip and a set of additional chips (step 302). Next, the process stacks the set of additional chips one at a time over the first chip, wherein each additional chip is horizontally offset from a preceding additional chip to form a ramp-stack (step 304).

FIG. 3B presents a flow chart illustrating in more detail the operations involved in performing step 304 in FIG. 3A in accordance with the disclosed embodiments. While stacking each additional chip, the process first applies an adhesive layer to a surface of a preceding chip in the ramp-stack (step 306). Next, the process uses a vacuum tool to pick up the additional chip and place the additional chip on the adhesive layer of the preceding chip, wherein the vacuum tool spans most of a surface of the additional chip and also provides planar support for the additional chip, which causes a holding force of the vacuum tool to flatten the additional chip prior to placement on the preceding chip (step 308). Next, the process snap-cures the adhesive layer using UV light (step 310). Finally, after all of the additional chips are stacked, the process performs a heat-based batch-curing operation on the entire ramp-stack to complete a permanent bonding process for the adhesive layers (step 312).

### System

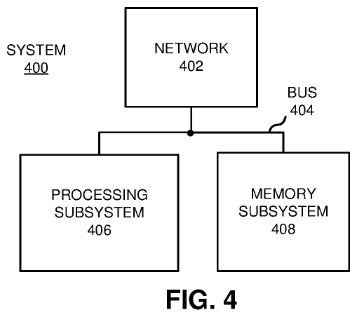

One or more of the preceding embodiments of the ramp-stacked chip assembly 100 illustrated in FIGS. 1A and 1B may be integrated into a computing system or device. More specifically, FIG. 4 illustrates a system 400 that includes a network 402 and a processing subsystem 406 comprising one or more processors and a memory subsystem 408 comprising a random-access memory. Within system 400, ramp-stacked chip assemblies can be used to interconnect processing components within processing subsystem 406. Ramp-stacked chip assemblies can also be used to interconnect processing components within processing subsystem 406 with memories within memory subsystem 408.

In general, components within system 400 may be implemented using a combination of hardware and/or software. Thus, system 400 may include one or more program modules or sets of instructions stored in a memory subsystem 408 (such as DRAM or another type of volatile or non-volatile computer-readable memory), which, during operation, may be executed by processing subsystem 406. Furthermore, instructions in the various modules in memory subsystem 408 may be implemented in: a high-level procedural language, an object-oriented programming language, and/or in an assembly or machine language. Note that the programming language may be compiled or interpreted, e.g., configurable or configured, to be executed by the processing subsystem.

Components in system 400 may be coupled by signal lines, links or buses, such as bus 404. These connections may include electrical, optical, or electro-optical communication of signals and/or data. Furthermore, in the preceding embodiments, some components are shown directly connected to one another, while others are shown connected via intermediate components. In each instance, the method of interconnection, or “coupling,” establishes some desired communication between two or more circuit nodes, or terminals. Such coupling may often be accomplished using a number of photonic or circuit configurations, as will be understood by those of skill in the art; for example, photonic coupling, AC coupling and/or DC coupling may be used.

In some embodiments, functionality in these circuits, components and devices may be implemented in one or more: application-specific integrated circuits (ASICs), field-programmable gate arrays (FPGAs), and/or one or more digital signal processors (DSPs). Furthermore, functionality in the preceding embodiments may be implemented more in hardware and less in software, or less in hardware and more in software, as is known in the art. In general, system 400 may be at one location or may be distributed over multiple, geographically dispersed locations.

System 400 may include: a switch, a hub, a bridge, a router, a communication system (such as a wavelength-division-multiplexing communication system), a storage area network, a data center, a network (such as a local area network), and/or a computer system (such as a multiple-core processor computer system). Furthermore, the computer system may include, but is not limited to: a server (such as a multi-socket, multi-rack server), a laptop computer, a communication device or system, a personal computer, a work station, a mainframe computer, a blade, an enterprise computer, a data center, a tablet computer, a supercomputer, a network-attached-storage (NAS) system, a storage-area-network (SAN) system, a media player (such as an MP3 player), an appliance, a subnotebook/netbook, a tablet computer, a smartphone, a cellular telephone, a network appliance, a set-top box, a personal digital assistant (PDA), a toy, a controller, a digital signal processor, a game console, a device controller, a computational engine within an appliance, a consumer-electronic device, a portable computing device or a portable electronic device, a personal organizer, and/or another electronic device.

Moreover, network 402 can be used in a wide variety of applications, such as: communications (for example, in a transceiver, an optical interconnect or an optical link, such as for intra-chip or inter-chip communication), a radio-frequency filter, a biosensor, data storage (such as an optical-storage device or system), medicine (such as a diagnostic technique or surgery), a barcode scanner, metrology (such as precision measurements of distance), manufacturing (cutting or welding), a lithographic process, data storage (such as an optical-storage device or system) and/or entertainment (a laser light show).

Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is:

1. A method for constructing a ramp-stacked chip assembly, comprising:
obtaining a set of semiconductor chips, including a first chip and a set of additional chips;
stacking the set of additional chips one at a time over the first chip, wherein each additional chip is horizontally offset from a preceding additional chip to form a ramp-stack; and
wherein stacking each additional chip involves:
applying an adhesive layer to a surface of a preceding chip in the ramp-stack; and
using a vacuum tool to pick up the additional chip and place the additional chip on the adhesive layer of the preceding chip;
wherein the vacuum tool spans most of a surface of the additional chip and also provides planar support for the additional chip, which causes a holding force of the vacuum tool to flatten the additional chip prior to placement on the preceding chip.

2. The method of claim 1, wherein the first chip is thicker than the additional chips to provide additional stiffness and reduce warpage.

3. The method of claim 1, wherein the first chip is a dummy chip that contains no active circuitry.

4. The method of claim 1, wherein the first chip is a functioning chip that includes active circuitry.

5. The method of claim 1, wherein the planar support is provided by a perimeter of a vacuum cavity in the vacuum tool, and also support pillars within the vacuum cavity.

6. The method of claim 1, wherein after each additional chip is placed on the adhesive layer of a preceding chip, the method further comprises snap-curing the adhesive layer using ultra-violet light (UV).

7. The method of claim 6, wherein after all of the additional chips are placed and snap-cured, the method further comprises performing a heat-based batch-curing operation on the entire ramp-stack to complete a permanent bonding process for the adhesive layers.

8. The method of claim 1, wherein the method further comprises:
attaching solder balls to bond pads located on edges of chips in the ramp-stack; and
affixing a ramp-component chip to the ramp-stack so that corresponding bond pads on the ramp-component chip are attached to the solder balls.

9. The method of claim 1, wherein the first chip and the additional chips were previously thinned through a chemical-mechanical polishing (CMP) operation prior to stacking.
